(19) United States
(12) Patent Application Publication
(10) Pub. No.: US 2024/0106483 A1
(43) Pub. Date: Mar. 28, 2024

(54) BELT-WORN FULL DUPLEX WIRELESS COMMUNICATION DEVICE

(71) Applicant: David Clark Company Incorporated, Worcester, MA (US)

(72) Inventors: Eric Motler, Northborough, MA (US); Brad Deschenes, Dudley, MA (US)

(73) Assignee: David Clark Company Incorporated, Worcester, MA (US)

(21) Appl. No.: 17/951,432

(22) Filed: Sep. 23, 2022

(51) Int. Cl. H04B 1/3827; H02J 7/00; H04B 10/40; H05K 1/14

(52) U.S. Cl. CPC H04B 1/385; H02J 7/0063; H04B 10/40; H05K 1/14; H04B 2001/3855; H05K 2201/10121

(57) ABSTRACT

A belt pack communication device is provided. An exemplary belt pack communication device includes at least one printed circuit board assembly (PCBA) positioned in a main body. The at least one PCBA has electrical components producing infrared (IR) signals. An IR transparent section is positioned on the main body. The IR transparent section includes at least one extrusion configured to allow the IR signals to pass through the IR transparent section and to receive external IR signals from at least a different communication device. A battery compartment for receiving a battery and delivering power to the at least one PCBA. The battery compartment is configured to isolate and seal the battery from the at least one PCBA. Several metal contacts are positioned at distal ends of the battery compartment. The metal contacts are configured to pass power from the battery to the at least one PCBA.

### BACKGROUND

Typical wireless belt pack communication devices rely on traditional I/O communication devices that are positioned within an enclosure requiring holes in integral plastic. Moreover, the manufacturing of wireless belt packs involves correct and repeatable assembly, including the custom assembly of selected components. The process is complex and labor-intensive leading to high labor costs with many opportunities for improper assembly that lead to field failures.

There is a need to provide a wireless belt pack communicate device having an enclosure having injection molded components.

### SUMMARY

According to one aspect of the subject matter described in this disclosure, a belt pack communication device is provided. The belt pack communication device includes at least one printed circuit board assembly (PCBA) positioned in a main body. The at least one PCBA has electrical components producing infrared (IR) signals. An IR transparent section is positioned on the main body. The IR transparent section includes at least one extrusion configured to allow the IR signals to pass through the IR transparent section and to receive external IR signals from at least a different communication device. A battery compartment for receiving a battery and delivering power to the at least one PCBA. The battery compartment is configured to isolate and seal the battery from the at least one PCBA. Several metal contacts are positioned at distal ends of the battery compartment. The metal contacts are configured to pass power from the battery to the at least one PCBA.

According to another aspect of the subject matter described in this disclosure, a battery enclosure is provided. The battery enclosure includes a battery compartment for receiving a battery. The battery compartment is configured to isolate and seal the battery from other components in the communication device. A battery access is positioned at one distal end of the battery compartment. The battery access is configured to seal the battery in the battery compartment. Several metal contacts are positioned at other distal ends of the battery compartment. The metal contacts are configured to pass power from the battery to the other components in the communication device.

According to another aspect of the subject matter described in this disclosure, a method of forming a belt pack communication device is provided. The method includes the following: providing at least one printed circuit board assembly (PCBA) in a main body, wherein the at least one PCBA comprises electrical components producing infrared (IR) signals; positioning an IR transparent section on the main body, the IR transparent section comprises at least one extrusion configured to allow the IR signals to pass through the IR transparent section and to receive external IR signals from at least a different communication device, wherein the injection molded IR transparent section forms a sealing surface to the main body; providing a battery compartment for receiving a battery and delivering power to the at least one PCBA, wherein the battery compartment is col figured to isolate and seal the battery from the at least one PCBA; and positioning a plurality of metal contacts at distal ends of the battery compartment, wherein the metal contacts are configured to pass power tram the battery to the at least one PCBA.

Additional features and advantages of the present disclosure is described in, and will be apparent from, the detailed description of this disclosure.

### BRIEF DESCRIPTION OF THE DRAWINGS

The disclosure is illustrated by way of example, and not by way of limitation, in the figures of the accompanying drawings in which like reference numerals are used to refer to similar elements. It is emphasized that various features may not be drawn to scale and the dimensions of various features may be arbitrarily increased or reduced for clarity of discussion.

FIG. 1 is a schematic diagram of a section view of wireless belt pack communication device, in accordance with some embodiments.

FIG. 2 is a block diagram representation of the wireless belt pack communication device of FIG. 1, in accordance with some embodiments.

FIG. 3 is a schematic diagram of a different section view of the wireless belt pack communication device of FIG. 1, in accordance with some embodiments.

FIG. 4 is a flowgraph of a process for forming a wireless belt pack communication device, in accordance with some embodiment.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context.

Described herein are example implementations of a wireless belt pack communication device having an optimized battery compartment and injection molded components. The wireless belt pack communication device includes an enclosure having an injection molded IR transparent top. The IR transparent top is used to transmit and receive IR signals through a printed circuit board assembly (PCBA) (internal to the enclosure) to a second wireless communication unit while also mounting a daughter-PCBA and headset connector. The transparent top also provides a sealing surface to the main body of the enclosure.

Also, the wireless belt pack communication device includes a battery compartment with a gasket around a screw-type access to the battery compartment. Metal contacts are used to pass power from the battery to the PCBA and separate the isolated and sealed battery compartment from the PCBA.

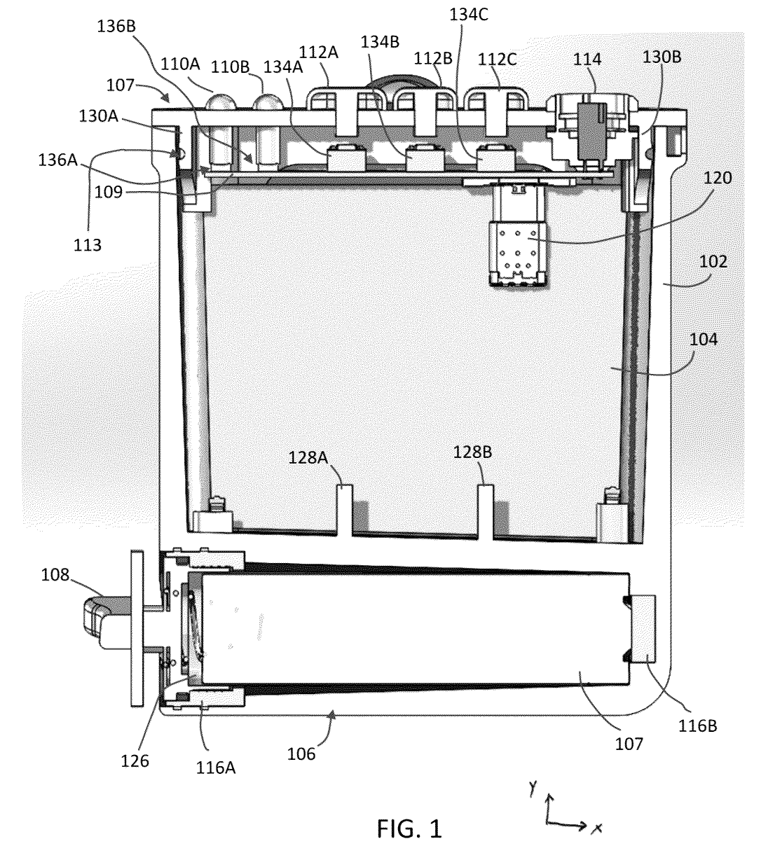

FIG. 1 is a schematic diagram of a section view of wireless belt pack communication device 100, in accordance with some embodiments. In particular, the wireless belt pack communication device 100 is configured to be a portable communication device. The wireless belt pack communication device 100 includes an enclosure 102 and a battery compartment 106. Enclosure 102 protects electrical components of wireless belt pack communication device 100. Also, enclosure 102 may contain weather-resistant materials applicable for rugged use.

Enclosure 102 includes an injection-molded infrared (IR) transparent top 107 used to pass IR signals through from the main print circuit board assembly (PCBA) 104 (internal to the enclosure) to another wireless communication system via IR LEDs 136A and 136B that are mounted to daughter-PCBA 109. A headset connector 114 is also mounted to the daughter-PCBA 109. The daughter-PCBA 109 is horizontally positioned in the x-direction. The ends of daughter-PCBA 109 are positioned on IR transparent top enclosure interface 130A and 130B, so daughter-PCBA 109 is appropriately secured. IR transparent top enclosure interface 130A and 130B are vertically oriented in the y-direction and integrally molded to top 107. Transparent top 107 include a number of button membranes 112A, 112B, and 112C. The button membranes 112A, 112B, and 112C are configured to activate switches 134A, 134B, and 134C when pressed by a user. Moreover, button membranes 112A, 112B, and 112C may be designed to protect switches 134A, 134B, and 134C for rugged use in selective environments.

In some embodiments, switches 134A, 134B, and 134C may be membrane switches specifically designed to open or close a switch when tactile interactions occur at button membranes 112A, 112B, and 112C.

Extrusions 110A and 110B receive and transmit the light signals and act as light pipes for LEDs 136A and 136B. The transparent top 107 also provides a sealing surface 113 to the main body of enclosure 102. The main body of enclosure 102 encloses the main PCBA 104.

PCBA 104 is positioned on PCBA holders 128A and 128B to be properly aligned within enclosure 102. PCBA holders 128A and 128B may be integrally molded to enclosure 102. A board-to-board connector 120 is configured to connect PCBA 104 electrically and physically to daughter PCBA 109. In some embodiments, device 100 may include more than one antenna for transmitting and receiving wireless signals. Several communication components, 220A-220D, are installed on main PCBA 104, which will be discussed later.

A battery 107 may be housed in the battery compartment 106 for powering wireless belt pack communication device 100. The battery compartment 106 is a hollowed cylindrical structure horizontally positioned in the x-direction that receives battery 107. The battery compartment 106 isolates battery 107 from the main PCBA 104. A battery access 108 is positioned at a distal end of the battery compartment 106. A user engages with battery access 108 for accessing battery 107. The battery access 108 may be configured as a battery screw top 108. The battery access 108 works with battery spring 126 to seal battery 107 in the battery compartment 106. In this implementation, one may unscrew the battery access 108 from battery compartment 106 to access battery 107. In some embodiments, the battery access 108 may have a silicon outer skin for retention.

Custom metal contacts 116A and 116B act as contacts to pass power from the battery to the main PCBA 104. Moreover, the metal contacts 116A and 116B are configured to provide a consistent IP68 seal between the battery compartment 106 and main PCBA 104. Over molding offers a superior seal against possible dust and moisture ingress if the battery compartment 106 is compromised, thus protecting the more sensitive PCBA electrical components.

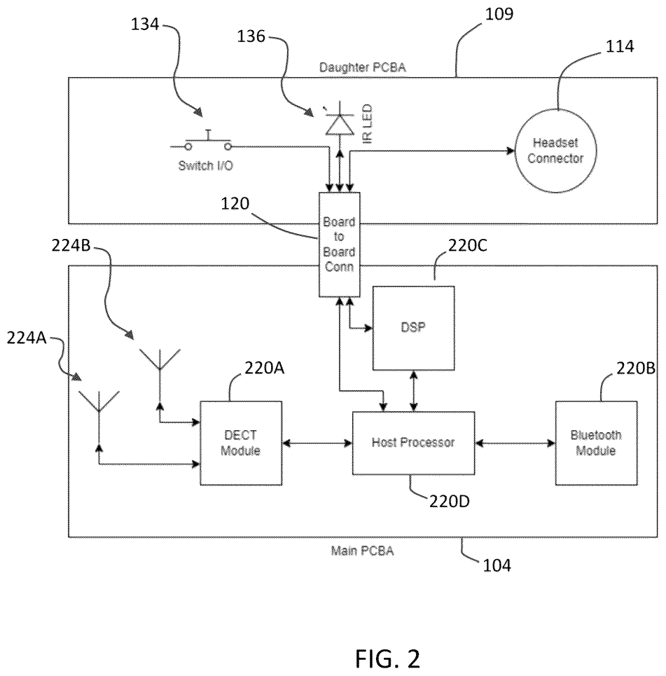

FIG. 2 is a block diagram representation of wireless belt pack communication device 100, in accordance with some embodiments. In particular, the main PCBA 104 may include a digital enhanced cordless telecommunication (DECT) module 220A, a Bluetooth module 220B, an onboard digital signal processor (DSP) 220C, and a host processor 220D. The DECT module 220A provides wireless operation, audio transmission, and reception of wireless belt pack communication device 100. Moreover, DEFT module 220A may use antennas 224A and 224B to facilitate wireless communications. In some embodiments, device 100 may include more or less antennas for transmitting and receiving wireless signals as shown in FIG. 2. The onboard Bluetooth module 220B allows for auxiliary devices to be locally paired to a belt pack for auxiliary audio needs, such as cell phones and Bluetooth-equipped radios. The onboard DSP 220C mixes and routes audio appropriately between a wired headset via headset connector 114, DECT module 220A, and Bluetooth module 220B. The host processor 220D configures and controls the operations of components 220A-220C of main PCBA 104.

The board-to-board connector 120 physically and electrically connects main PCBA 104 and daughter PCBA 109. Moreover, the board-to-board connector 120 is configured to receive and send signals between the various component in main PCBA 104 and daughter PCBA 109. In particular, the switch 134, which can be any one of the switches 134A, 134B, and 134C of FIG. 1, of daughter PCBA 109 may be connected to board-to-board connector 120. The IR LED 136, which can be any one of the IR LED 136A and 136B of FIG. 1, of daughter PCBA 109 may be connected to board-to-board connector 120. DSP 220C and host processor 220D of main PCBA 104 may be connected to board-to-board connector 120 for receiving and sending signals to the components of daughter PCBA 109.

The DECT protocol utilizes a star configuration that includes one fixed and multiple portable communication devices. These portable communication devices may register to the fixed communication device to establish a secure wireless connection. IR may be utilized so that the fixed communication device can broadcast its unique ID, so a portable communication device can receive the ID for registration requirements. The proximity registration scheme may be limited in range to mitigate unintended registration of nearby systems simultaneously.

The wireless belt pack communication device 100 may be a portable communication device under DECT. In some embodiments, wireless belt pack communication device 100 may operate as a fixed communication device under DECT if appropriate software is loaded.

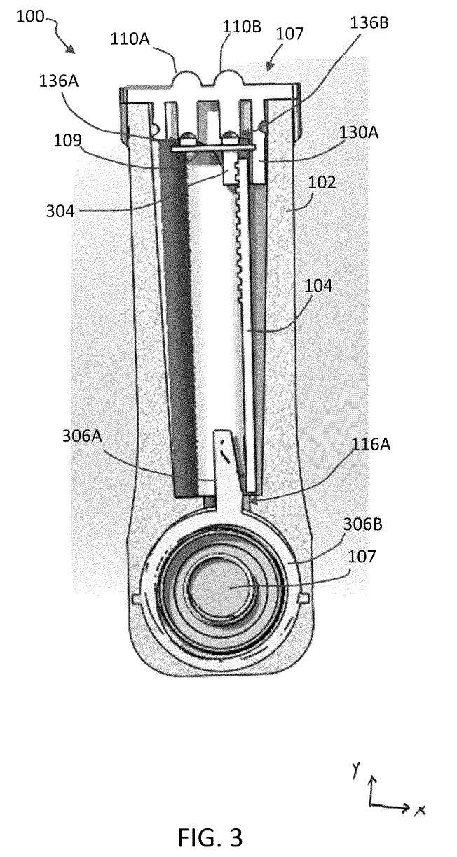

FIG. 3 is a schematic diagram of a side view of wireless belt pack communication device 100, in accordance with some embodiments. In particular, FIG. 2 shows main PCBA 104 and daughter PCBA 109 connected with electrical connector 304 which has mating ends mounted on each board. The electrical connector 204 is vertically oriented (in the y-direction) on both the main PCBA 104 and the daughter PCBA 109. Once the electrical connection between main PCBA 104 and electrical connector 304 is established, IR signals from IR LEDs 136A and 136B may be received by extrusions 110A or 110B via daughter-PCBA 109.

Metal contact 116A has a vertical portion 306A and a circular portion 306B being integrally molded. The vertical portion 306A is vertically oriented in the y-direction and establishes an electrical connection with the main PCBA 104 to provide power from battery 107 The circular portion 306B surrounds the outside surface of one end of battery compartment 106 to draw power from the battery 107. Note that metal contact 116B has vertical and circular portions similar to metal contact 116A but is positioned on the other end of battery compartment 106. In some embodiments, vertical portion 306A may be over molded within enclosure 102 to provide rigidity and support for establishing the IP68 seal.

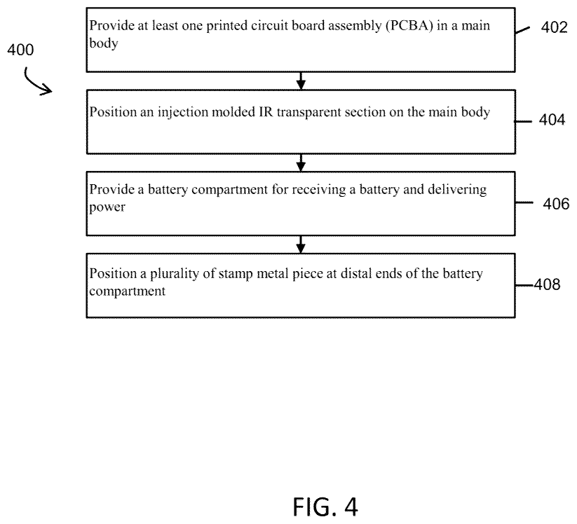

FIG. 4 is a flowgraph of a process 400 for forming a wireless belt pack communication device, in accordance with some embodiment. Process 400 includes providing at least one printed circuit board assembly (PCBA) (such as main PCBA 104) in a main body (Step 402). The at least one PCBA includes at least one electrical component (such such as IR LEDs 136A and 136B) producing infrared (IR) signals. Process 400 includes positioning an injection molded IR transparent section (such as injection molded IR transparent top 107) on the main body (Step 304). The injection molded IR transparent section includes at least one extrusion (such as extrusion 110A or 110B) configured to allow the IR signals to pass and receive external IR signals from at least a different communication device. The injection molded IR transparent section forms a sealing surface to the main body.

Process 400 includes providing a battery compartment (such as battery compartment 106) for receiving a battery and delivering power to the at least one PCBA (Step 406). The battery compartment is configured to isolate and seal the battery from the at least one PCBA. Furthermore, process 400 includes positioning a plurality of metal contacts (such as metal contacts 116A and 116B) at distal ends of the battery compartment (Step 408). The metal contacts are configured to pass power from the battery to the at least one PCBA.

The disclosure describes a wireless belt pack communication device having an optimized battery compartment and injection molded components. The advantages provided by the wireless belt pack communication device include a ruggedized housing for many hours of successful operation in the most demanding environments and use scenarios. Moreover, the wireless belt pack communication device would be a compact structure using IP68 design techniques with the incorporation of IR transparent materials to facilitate DECT registration at a meager relative cost.

When coupled with appropriate headsets, the wireless belt pack communication device facilitates normal speaking and hearing levels in environments where talking and hearing are unsafe or unintelligible. Also, the wireless belt pack communication device may be used where users require instantaneous full duplex communication in high noise and potentially wet environments. Furthermore, one can use the wireless belt pack communication device in a standalone manner to provide an ad-hoc communication system and be integrated to expand the capabilities and user count of specific intercom systems.

Reference in the specification to “one implementation” or “an implementation” means that a particular feature, structure, or characteristic described in connection with the implementation is included in at least one implementation of the disclosure. The appearances of the phrase “in one implementation,” “in some implementations,” “in one instance,” “in some instances,” “in one case,” “in some cases,” “in one embodiment,” “in some embodiments” in various places in the specification are not necessarily all referring to the same implementation or embodiment.

Finally, the above descriptions of the implementations of the present disclosure have been presented for the purposes of illustration and description. It is not intended to be exhaustive or to limit the present disclosure to the precise form disclosed. Many modifications and variations are possible in light of the above teaching. It is intended that the scope of the present disclosure be limited not by this detailed description, but rather by the claims of this application. As will be understood by those familiar with the art, the present disclosure may be embodied in other specific forms without departing from the spirit or essential characteristics thereof. Accordingly, the present disclosure is intended to be illustrative, but not limiting, of the scope of the present disclosure, which is set forth in the following claims.

What is claimed is:

1. A belt pack communication device comprising:
at least one printed circuit board assembly (PCBA) positioned in a main body, wherein the at least one PCBA comprises electrical components producing infrared (IR) signals;
an IR transparent section positioned on the main body, the IR transparent section comprises at least one extrusion configured to allow the IR signals to pass through the IR transparent section and to receive external IR signals from at least a different communication device;
a battery compartment for receiving a battery and delivering power to the at least one PCBA, wherein the battery compartment is configured to isolate and seal the battery from the at least one PCBA; and
a plurality of metal contacts positioned at distal ends of the battery compartment, wherein the metal contacts are configured to pass power from the battery to the at least one PCBA.

2. The belt pack communication device of claim 1, wherein the at least one PCBA is coupled to a second PCBA.

3. The belt pack communication device of claim 2, wherein the at least one PCBA comprises a plurality of protrusions coupled to the second PCBA.

4. The belt pack communication device of claim 1, wherein the IR transparent section is an IR injection-molded transparent section positioned on the main body.

5. The belt pack communication device of claim 1, wherein the IR transparent section receives the IR signals from a second PCBA.

6. The belt pack communication device of claim 1, wherein the IR transparent section forms a sealing surface to the main body.

7. The belt pack communication device of claim 1, wherein the battery compartment receives a gasket configured to securely contain the battery in the battery compartment.

8. The belt pack communication device of claim 7, wherein the battery compartment comprises a screw-type access for securely locking the gasket in the battery compartment.

9. A battery enclosure for a communication device comprising:
a battery compartment for receiving a battery, wherein the battery compartment is configured to isolate and seal the battery from other components in the communication device;
a battery access positioned at one distal end of the battery compartment, wherein the battery access is configured to securely place the battery in the battery compartment; and
a plurality of metal contacts positioned at other distal ends of the battery compartment, wherein the metal contacts are configured to pass power from the battery to the other components in the communication device.

10. The battery enclosure of claim 9, wherein the battery access is a screw-type access for securely locking the battery in the battery compartment.

11. The battery enclosure of claim 9, wherein the battery access comprises a silicon outer skin for retention.

12. The battery enclosure of claim 9, wherein each of the metal contacts comprises a circular portion positioned around one distal end of the battery access.

13. The battery enclosure of claim 10, wherein each of the metal contacts comprises a vertical portion positioned on the at least one PCBA.

14. A method of forming a belt pack communication device, the method comprising:
providing at least one printed circuit board assembly (PCBA) in a main body, wherein the at least one PCBA comprises electrical components producing infrared (IR) signals;
positioning an IR transparent section on the main body, the IR transparent section comprises at least one extrusion configured to allow the IR signals to pass through the IR transparent section and to receive external IR signals from at least a different communication device, wherein the injection molded IR transparent section forms a sealing surface to the main body;
providing a battery compartment for receiving a battery and delivering power to the at least one PCBA, wherein the battery compartment is configured to isolate and seal the battery from the at least one PCBA; and
positioning a plurality of metal contacts at distal ends of the battery compartment, wherein the metal contacts are configured to pass power from the battery to the at least one PCBA.

15. The method of claim 14, wherein the at least one PCBA is coupled to a second PCBA.

16. The method of claim 15, wherein the at least one comprises a plurality of protrusions coupled to the second PCBA.

17. The method of claim 14, wherein the IR transparent section is an IR injection-molded transparent section positioned on the main body.

18. The method of claim 14, wherein positioning the IR transparent section comprises receiving the IR signals from a second PCBA.

19. The method of claim 1, wherein positioning the IR transparent section comprises forming a sealing surface to the main body.

20. The method of claim 1, wherein providing the battery compartment comprises providing a battery access configured to securely contain the battery in the battery compartment.
